(19) United States
(12) Patent Application Publication
(10) Pub. No.: US 2011/0227133 A1
(43) Pub. Date: Sep. 22, 2011

(54) SEMICONDUCTOR DEVICE AND STANDARD CELL

(75) Inventor: Toshiki Morimoto, Kanagawa (JP)

(73) Assignee: KABUSHIKI KAISHA TOSHIBA, Tokyo (JP)

(21) Appl. No.: 12/883,667

(22) Filed: Sep. 16, 2010

(30) Foreign Application Priority Data
Mar. 19, 2010 (JP) 2010-064719

(51) Int. Cl. H01L 27/08; H01L 29/06

(52) U.S. Cl. 257/204; 257/207; 257/E27.046; 257/E29.007

(57) ABSTRACT

According to the embodiments, standard cells are arranged in an array in a semiconductor device. In the standard cell, a first diffusion area with a plurality of transistors formed in a main surface region of a semiconductor substrate is formed in a region sandwiched between two power supply lines arranged on the semiconductor substrate. Further, the standard cell includes a potential supplying unit. The potential supplying unit is formed in the main surface region of the semiconductor substrate by a diffusion layer of the same conductive type as that of the first diffusion area and is electrically connected directly to the diffusion area through a contact from the lower portion of the power supply line, to supply a potential from the power supply line to the first diffusion area.

### CROSS-REFERENCE TO RELATED APPLICATIONS

This application is based upon and claims the benefit of priority from Japanese Patent Application No. 2010-64719, filed on Mar. 19, 2010; the entire contents of which are incorporated herein by reference.

### FIELD

Embodiments described herein relate generally to a semiconductor device and a standard cell.

### BACKGROUND

In a semiconductor integrated circuit, higher integration is desired from the viewpoint of manufacturing cost and yield. The semiconductor integrated circuit includes numerous standard cells used as a cell forming a logic circuit in a semiconductor chip. Also in the standard cell, a size reduction of each cell and a high integration of the cells are important. In this standard cell, a cell with substrate areas provided in its both ends in the vertical direction is used widely as a means for supplying a potential to a well or a substrate.

As a method for realizing a high integrated standard cell, for example, a semiconductor device is disclosed in Japanese Patent Publication Laid-Open No. 2009-32788, in which a first diffusion layer (for example, reference numeral 3p in FIG. 1) is a transistor area of the standard cell in a substrate, a second diffusion layer (for example, reference numeral 4n in FIG. 1) of the conductive type opposite to the first diffusion layer is provided as a tap adjacently to the first diffusion layer, under the wiring layer, and the first diffusion layer and the second diffusion layer are respectively connected to the wiring layer through contacts.

The semiconductor device disclosed in the above Japanese Patent Publication Laid-Open No. 2009-32788, however, has to secure a distance between the first diffusion layer and the second diffusion layer in order to isolate the standard cell from the tap because the first diffusion layer forming the standard cell and the second diffusion layer forming the tap are different diffusion layers in conductive type. Therefore, a problem is that the size of a diffusion area for forming a transistor in a cell becomes smaller. In other words, in order to secure the size of the diffusion area for a transistor corresponding to the distance, the size of a cell must be enlarged.

Alternatively, with the development of EDA tool in these days, there is established a method of automatically arranging each standard cell which is formed in a cell structure (tapless structure) for making the best use of a transistor area without any substrate area, as a cell and arranging dedicated cells (tap cell) in the respective cell lines at some intervals as a means for supplying a potential to a well, as a measure for increase of degree of standard cell integration. Even in the case of this standard cell of the tapless structure, further higher integration is desired from the viewpoint of the manufacturing cost and yield.

Further, there is a tendency to delay the miniaturization of wiring and contact, in spite of the progress in miniaturization technology of transistor. Accordingly, the space occupied by the wiring and contact is relatively getting larger in a cell and it becomes difficult to accommodate a desired design pattern into a cell.

### BRIEF DESCRIPTION OF THE DRAWINGS

FIGS. 1A to 1C are views each showing the structure of a standard cell according to a first embodiment.

FIG. 2 is a view showing an example of a layout pattern of transistors in the standard cell according to the first embodiment.

FIG. 3 is a view showing an example of the layout pattern of the standard cells in a semiconductor device according to the first embodiment.

FIG. 4 is a view showing another example of the layout pattern of transistors in the standard cell according to the first embodiment.

FIG. 5 is a view showing an example of the layout pattern of transistors in the standard cell having the tapless structure well known by the inventor as a comparative example.

FIG. 6 is a view showing an example of the layout pattern of transistors in the standard cell having the tapless structure well known by the inventor as the comparative example.

FIG. 7 is a view showing an example of the layout pattern of the standard cells well known by the inventor in a semiconductor device as the comparative example.

FIG. 8 is a plan view showing the structure of a standard cell according to a second embodiment.

FIGS. 9A and 9B are schematic views for use in describing the structure of a transistor area in the standard cell according to the second embodiment.

FIGS. 10A and 10B are schematic views for use in describing the structure of the transistor area in the standard cell according to the second embodiment.

FIG. 11 is a view showing an example of the layout pattern of the standard cells in a semiconductor device according to the second embodiment.

### DETAILED DESCRIPTION

In general, according to one embodiment, a semiconductor device attained as follows. In a semiconductor device, standard cells are arranged in an array. In a standard cell, a first diffusion area with a plurality of transistors formed in a main surface region of a semiconductor substrate is formed between two power supply lines arranged above the semiconductor substrate. The standard cell is provided with a potential supplying unit. The potential supplying unit is formed in the main surface region of the semiconductor substrate by a diffusion layer having the same conductive type as the first diffusion area and electrically directly connected to the diffusion area downwardly from the power supply line through a contact, to supply a potential from the power supply line to the first diffusion area.

Exemplary embodiments of a semiconductor device and a standard cell will be explained below in detail with reference to the accompanying drawings. The present invention is not limited to the following embodiments. In each of the following drawings and between the drawings, the scale of each component may be different from the actual case, for the sake of easy understanding. Even in a plan view, hatching may be put there for the sake of easy view.

### First Embodiment

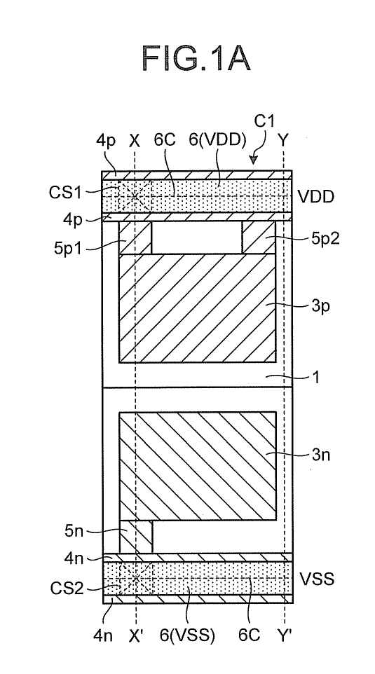

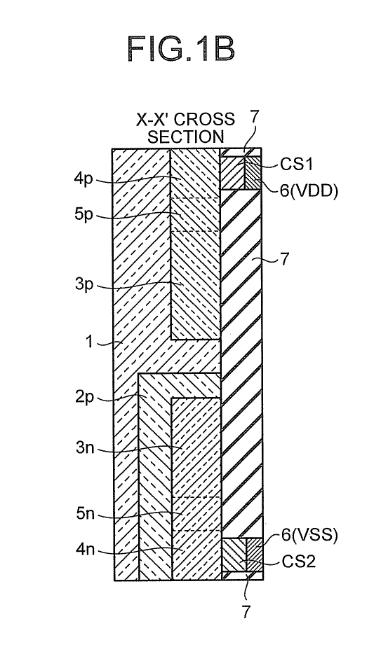

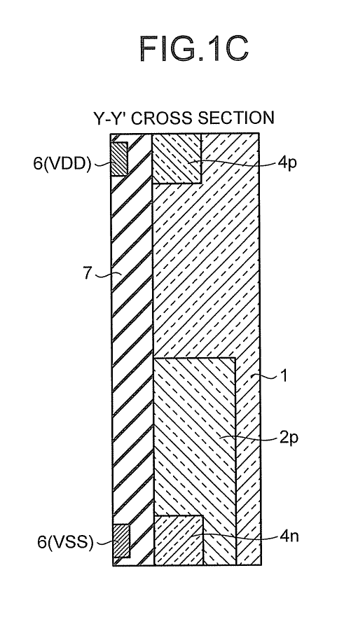

FIGS. 1A to 1C are views each showing the structure of a standard cell C1 according to a first embodiment. FIG. 1A is a plan view of the standard cell. FIG. 1B is a cross-sectional view taken along the X-X′ line in FIG. 1A. FIG. 1C is a cross-sectional view taken along the Y-Y′ line in FIG. 1A. The standard cell C1 is formed in a cell structure (tapless structure) designed not to have any substrate area in each cell for making an effective use of the transistor area. A plurality of gate wirings are arranged and a plurality of transistors are formed in the standard cell; however, the description of the gate wirings is omitted in FIGS. 1A to 1C.

The standard cell C1 is formed in a main surface (element forming surface) region of a semiconductor substrate (hereinafter, referred to as “substrate”) 1 formed, for example, of n-type silicon. The standard cell C1 is formed by using a MOS (Metal Oxide Semiconductor) transistor (hereinafter, referred to as “transistor”) as a semiconductor element. A transistor and a contact thereon and a wiring layer can be formed according to a well-known manufacturing method.

A p-type well 2p is formed in a part of the main surface region of the substrate 1 with the standard cell C1 formed there. The p-type well 2p is formed with the p-type impurities implanted into the substrate 1 according to the well-known photolithography and ion implantation technique. A substantially rectangular n-type diffusion area 3n forming an n-channel type transistor area and a source/drain is formed in the p-type well 2p. The n-type diffusion area 3n is formed with the n-type impurities implanted into the p-type well 2p according to the well-known photolithography and ion implantation technique.

A substantially rectangular p-type diffusion area 3p forming a p-channel type transistor area and a source/drain is formed in a part of the main surface region of the substrate 1. The p-type diffusion area 3p is formed with the p-type impurities implanted into the substrate 1 according to the well-known photolithography and ion implantation technique.

A p-type diffusion area 4p is formed in the upper portion of the standard cell C1 in the longitudinal direction of the drawing (the vertical direction of FIGS. 1A to 1C). When the standard cell C1 is put horizontally, the p-type diffusion area 4p is formed under a power supply line 6 (VDD) along the power supply line 6 (VDD) formed by a metal wiring layer sharing the potential with another cell. The p-type diffusion area 4p forms a part of a power supplying unit (source node) which supplies a potential from the power supply line 6 (VDD) to the p-type diffusion area 3p (p-channel type transistor area). In the upper end portion of the standard cell C1, the power supply line 6 (VDD) is provided substantially in parallel with the upper end side of the standard cell C1.

The p-type diffusion area 4p and the power supply line 6 (VDD) are respectively symmetric in each width with respect to a center line 6c in the longitudinal direction of the power supply line 6 (VDD). Therefore, even when another standard cell C1 is disposed above, sharing the power supply line 6 (VDD), there does not occur a design rule violation caused by a difference in the width of the p-type diffusion area 4p and the power supply line 6 (VDD).

The p-type diffusion area 4p is electrically connected to the power supply line 6 (VDD) through a contact CS1 provided on the p-type diffusion area 4p. The p-type diffusion area 4p is formed in the same process as that of the p-type diffusion area 3p. The contact CS1 is arranged so that the center of the contact is overlapped with the center line 6c in the longitudinal direction of the power supply line 6 (VDD).

The p-type diffusion area 4p is electrically connected to the p-type diffusion area 3p through a p-type diffusion area 5p (5p1 and 5p2). The p-type diffusion area 5p (5p1 and 5p2) forms a part of the source node of the p-type diffusion area 3p (p-channel type transistor area) together with a part of the p-type diffusion area 4p. The p-type diffusion area 5p, and a region of the p-type diffusion area 4p corresponding to the p-type diffusion area 5p, which connects the contact CS1 and the p-type diffusion area 5p, form a source node of the p-type diffusion area 3p (p-channel type transistor area). The p-type diffusion area 5p is formed in the same process as that of the p-type diffusion area 3p and the p-type diffusion area 4p. The position and the number of the p-type diffusion areas 5p can be set properly according to a layout pattern of the transistors in the p-type diffusion area 3p and it is not restricted to this as far as the design rule is satisfied at the arrangement of the neighboring standard cells.

In the p-type well 2p, an n-type diffusion area 4n is formed in the lower portion of the standard cell C1 in the longitudinal direction of the drawings (the vertical direction of FIGS. 1A to 1C). When the standard cell C1 is put horizontally, the n-type diffusion area 4n is formed under the power supply line 6 (VSS) along the power supply line 6 (VSS) formed by a metal wiring layer sharing the potential with another cell. The n-type diffusion area 4n forms a part of a power supplying unit (source node) which supplies a potential from the power supply line 6 (VSS) to the n-type diffusion area 3n (n-channel type transistor area). In the lower end portion of the standard cell C1, the power supply line 6 (VSS) is provided substantially in parallel with the lower end side of the standard cell C1.

The n-type diffusion area 4n and the power supply line 6 (VSS) are respectively symmetric in each width with respect to the center line 6c in the longitudinal direction of the power supply line 6 (VSS). Therefore, even when another standard cell C1 is disposed below, sharing the power supply line 6 (VSS), there does not occur a design rule violation caused by a difference in the width of the n-type diffusion area 4n and the power supply line 6 (VSS).

The n-type diffusion area 4n is electrically connected to the power supply line 6 (VSS) through a contact CS2 provided on the n-type diffusion area 4n. The n-type diffusion area 4n is formed in the same process as that of the n-type diffusion area 3n. The contact CS2 is arranged so that the center of the contact is overlapped with the center line 6c in the longitudinal direction of the power supply line 6 (VSS).

The n-type diffusion area 4n is electrically connected to the n-type diffusion area 3n through an n-type diffusion area 5n. The n-type diffusion area 5n forms a part of the source node of the n-type diffusion area 3n (n-channel type transistor area) together with a part of the n-type diffusion area 4n. The n-type diffusion area 5n, and a region of the n-type diffusion area 4n corresponding to the n-type diffusion area 5n, which connects the contact CS2 and the n-type diffusion area 5n, form a source node of the n-type diffusion area 3n (n-channel type transistor area). The n-type diffusion area 5n is formed in the same process as that of the n-type diffusion area 3n and the n-type diffusion area 4n. The position and the number of the n-type diffusion areas 5n can be set properly according to a layout pattern of the transistors in the n-type diffusion area 3n and it is not restricted to this as far as the design rule is satisfied at the arrangement of the neighboring standard cells.

On the substrate 1, an insulating layer 7 is formed in a region where the contact CS1, the contact CS2, the power supply line 6 (VDD), and the power supply line 6 (VSS) are not formed, at the same level as these layers.

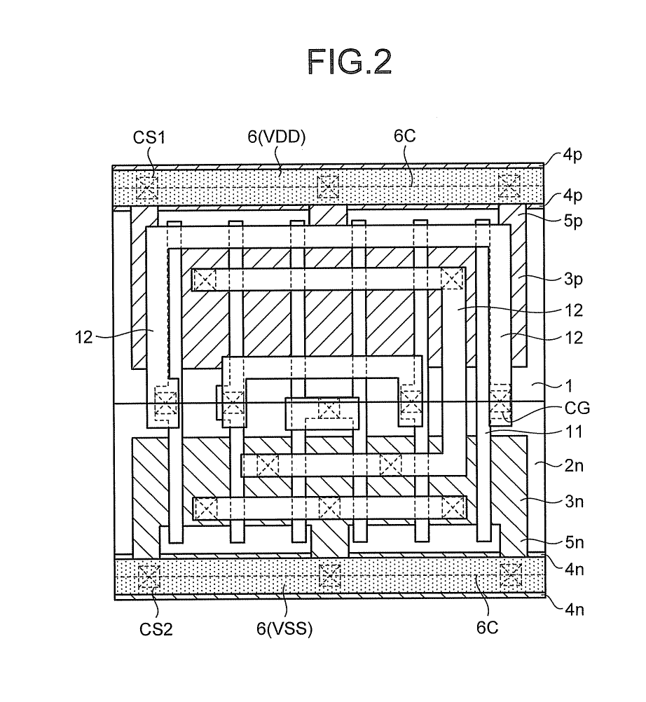

FIG. 2 is a view showing an example of the layout pattern of transistors in the standard cell C1 according to the first embodiment. FIG. 2 shows gate wirings 11 for the transistors, contacts CG connected with the gate wirings 11, and leading wirings 12 connected to the contacts CG for supplying a potential to the gate wirings 11. As shown in FIG. 2, in the standard cell C1, the p-type diffusion area 3p and the n-type diffusion area 3n which are the transistor areas do not have any drawer of a source node (metal wiring layer) from the power supply line 6. Therefore, in the transistor area, there is a space for the wirings and the wirings for transistors and the contacts can be freely arranged, thereby improving the flexibility of the arrangement within a cell. Further, the cell size can be reduced through appropriate arrangement in a cell. In addition, a desired layout pattern can be realized without using a multi-layered wiring. Further, a load on a layout tool can be reduced at a time of designing a semiconductor chip by using the standard cells C1, the time of designing a semiconductor chip can be shortened, and the semiconductor chip size can be reduced.

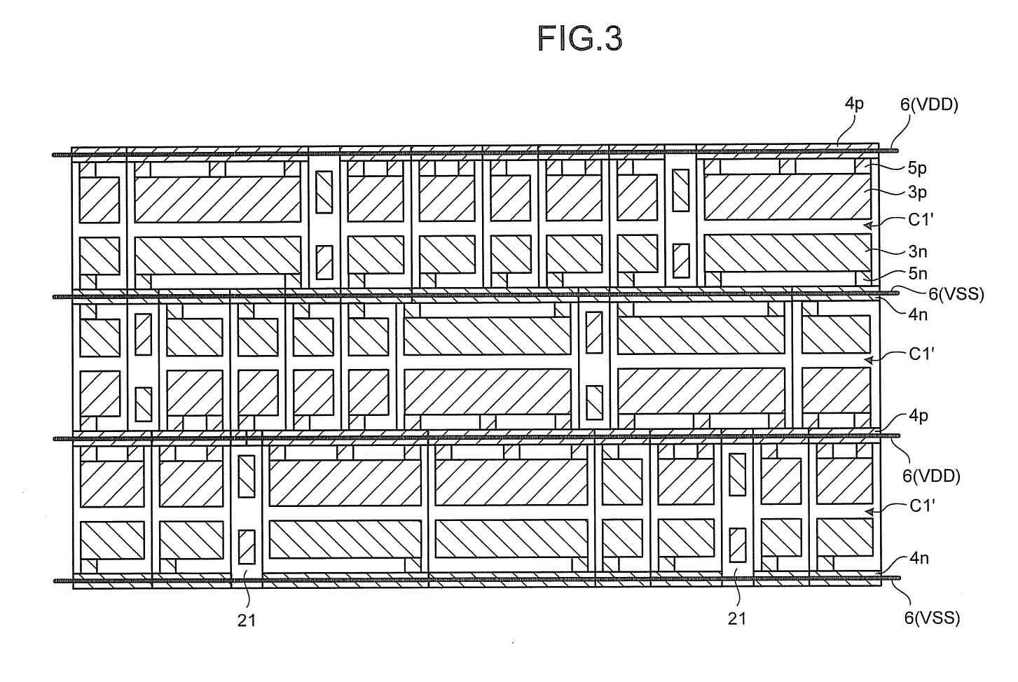

FIG. 3 is a view showing an example of the layout pattern of the standard cells in a semiconductor device according to the first embodiment. In the semiconductor device, a plurality of standard cells C1′ having the same structure as the above mentioned standard cell C1 are arranged in an array. Dedicated cells (tap cell) 21 are arranged in each cell line at some intervals as a means for supplying a potential to the well.

The standard cells C1′ in a first line and the standard cells C1′ in a second line share the power supply line 6 (VSS) and the n-type diffusion area 4n. The standard cells C1′ in the second line and the standard cells C1′ in a third line share the power supply line 6 (VDD) and the p-type diffusion area 4p.

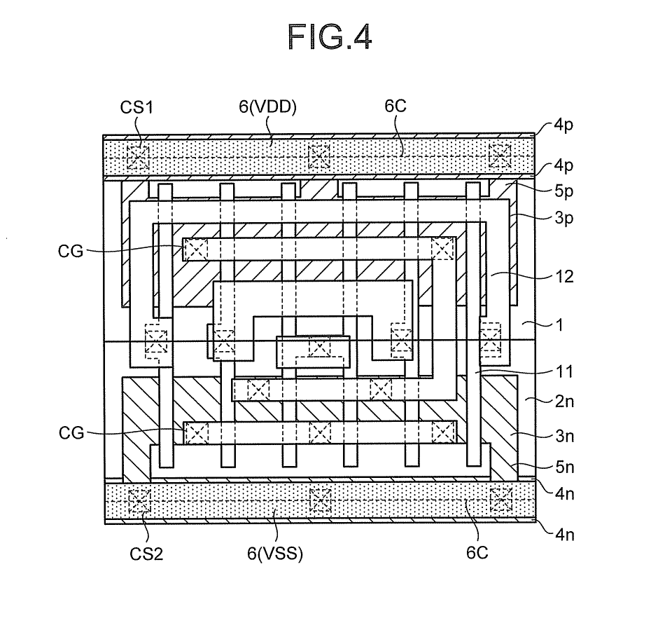

FIG. 4 is a view showing another example of the layout pattern of transistors in the standard cell C1 according to the first embodiment. FIG. 4 shows a layout pattern in which the cell is shortened in the vertical direction of the drawing with the same circuit used in the standard cell C1 as shown in FIG. 2. This is the example with the unused space of the transistor area in the layout pattern shown in FIG. 2 reduced. In this case, the cell is shortened in the vertical direction, thereby realizing a reduction in the cell size.

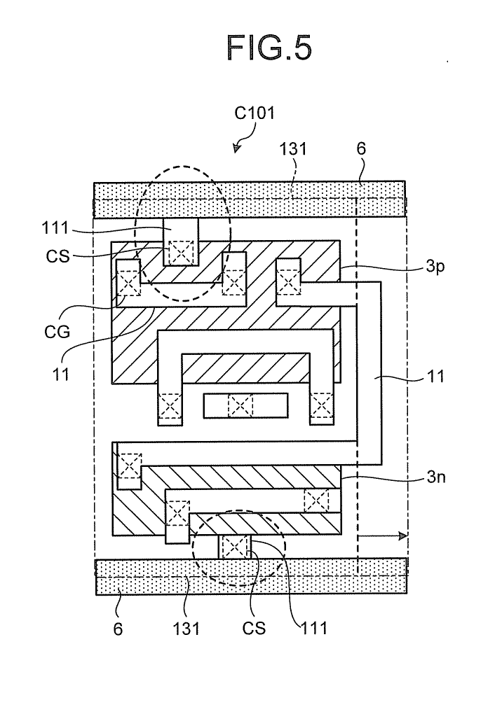

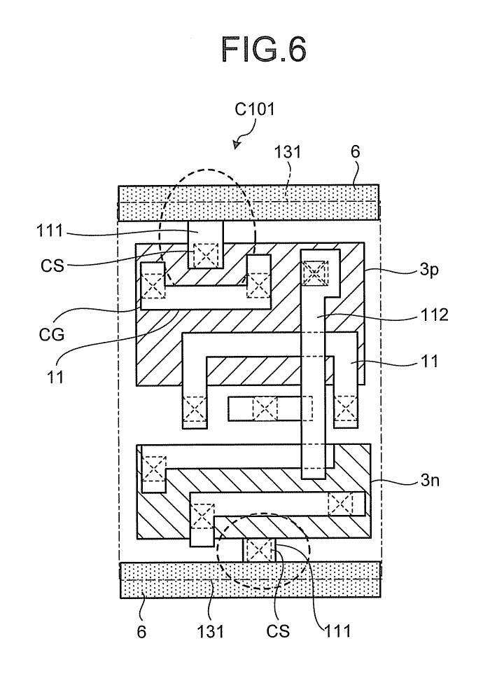

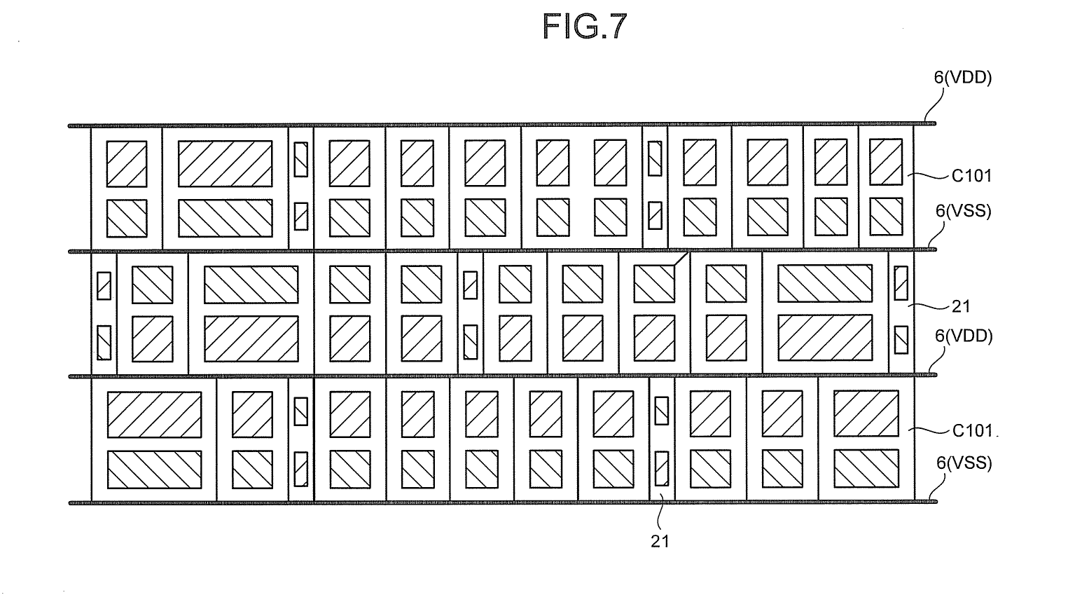

FIGS. 5 and 6 are views each showing an example of the layout pattern of transistors in a standard cell C101 having the tapless structure, well known by the inventor and el., as a comparative example. FIG. 7 is a view showing an example of the layout pattern of the above standard cells C101 well known by the inventor in a semiconductor device as the comparative example. In the semiconductor device, a plurality of the standard cells C101 having the tapless structure well known by the inventor of the comparative example, are arranged in an array. The standard cell C101 shown in FIG. 5 includes a substantially rectangular p-type diffusion area 3p and a rectangular n-type diffusion area 3n forming transistors, and power supply lines 6 each formed by a metal wiring layer and arranged symmetrically with respect to a cell boundary 131 at its both sides. In FIG. 5, metal wiring layers 111 as the source nodes and metal wiring layers 11 used in the internal wiring are laid out and the description of the gate wiring is omitted.

Here, the source node for the transistors is formed by drawing the metal wiring layer 111 from the power supply line 6. The metal wiring layer 111, the source node, is connected to the p-type diffusion area 3p or the n-type diffusion area 3n through a contact CS. In this cell structure of the comparative example well known by the inventor, the larger number of the metal wirings for obtaining a source contact is required in the vicinity of the power supply line 6 according as the number of the source nodes is getting larger in a circuit, hence to reduce the space for a necessary wiring and contact within a cell. When a necessary wiring pattern is realized only with the metal wiring layer 11 in the first layer, the cell size cannot help being enlarged.

In order not to increase the cell size, a second or a third metal wiring layer 112 is necessary. In this case, the wiring resource connecting the cells is decreasing. When a plurality of cells are arranged in an array, the interval of the adjacent cells has to be widened in order to lay out a wiring connecting the cells. Further, the upper metal wiring layer is required, which increases the chip size and the manufacturing cost.

The standard cell according to the first embodiment, however, has no drawing line of the source node from the power supply line 6 on the transistor area as mentioned above, with a good flexibility and free from the above problems.

In the standard cell thus constituted according to the first embodiment, a power supplying unit (source node) for supplying a potential from the power supply line 6 to the transistor area is formed by a diffusion layer embedded in the substrate 1 under the power supply line 6. The power supplying unit is electrically connected to the transistor area directly through the diffusion layer embedded in the substrate 1. Namely, the power supplying unit (source node) is not put on the transistor area. Accordingly, the flexibility of the arrangement of wirings inside the transistor area is improved, and the number of the transistors integrated in a cell can be increased without enlarging the cell size, thereby realizing a high integrated standard cell. When a predetermined number of the transistors is integrated in a cell, the cell size of the standard cell can be reduced.

Since the metal wiring layer as the source node is not used, the wiring in a cell with a small number of the metal wiring layers is possible, hence to restrain a multi-layered wiring. Therefore, the size of a semiconductor chip can be reduced. Further, a connection between the cells using a layout tool such as EDA tool can be realized with a smaller number of layers, thereby to reduce the load on the layout tool and shorten the time for semiconductor chip design. Further, along with a reduction in the number of the wiring layers, the number of mask layers for use in manufacturing a wiring can be reduced, thereby saving the manufacturing cost.

Since the source node and the transistor area are formed by the same kind of the diffusion layer, the interval between the source node and the transistor area can be set shorter. Therefore, it is possible to secure a wide transistor area in a cell, thereby realizing a high integrated standard cell.

As mentioned above, according to the first embodiment, a high integrated semiconductor device can be realized.

### Second Embodiment

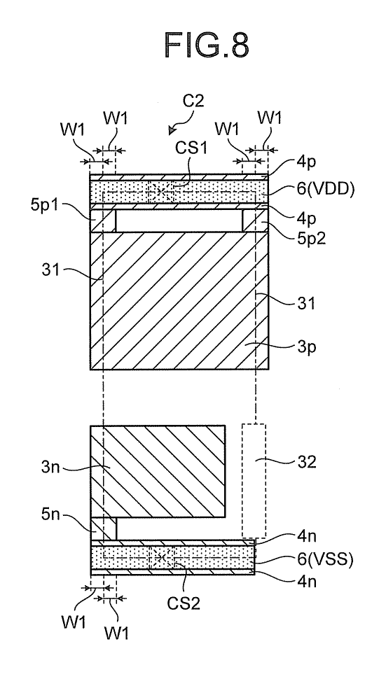

FIG. 8 is a plan view showing the structure of a standard cell C2 according to a second embodiment. The standard cell C2 is formed in that the transistor area, the source node, and the power supply line 6 are expanded across a cell boundary 31 in the width direction of a cell (the horizontal direction in FIG. 8) when a source node is positioned at an end/ends of the cell in the width direction, based on the basic structure of the standard cell C1 shown in FIG. 1A. In other words, the transistor area, the source node, and the power supply line 6 are protruded from the cell boundary 31 in the width direction of the cell. Also in FIG. 8, the description of gate wirings is omitted. In FIG. 8, the same reference numerals are respectively attached to the same components as those of the standard cell C1 shown in FIG. 1A.

A p-type diffusion area 5p1 forming a source node is expanded outward from the cell boundary 31 in the width direction of the cell and it has double the width W1 with the cell boundary 31 put in the middle. The power supply line 6 (VDD), a p-type diffusion area 4p, and a p-type diffusion area 3p are expanded outward from the cell boundary 31 to the same position as the p-type diffusion area 5p1 at the respective one ends (left side) in the width direction of the cell. The region of the p-type diffusion area 3p, the p-type diffusion area 5p1, the p-type diffusion area 4p, and the power supply line 6 (VDD) corresponding to the width W1 expanded across the cell boundary 31 is shared with the adjacent cell (not illustrated) in the width direction of the cell when the standard cells C2 are arranged in an array.

Similarly, a p-type diffusion area 5p2 forming a source node is expanded outward from the cell boundary 31 in the width direction of the cell and it has double the width W1 with the cell boundary 31 put in the middle. The power supply line 6 (VDD), the p-type diffusion area 4p, and the p-type diffusion area 3p are expanded outward from the cell boundary 31 to the same position as the p-type diffusion area 5p2 at the respective other ends (right side) in the width direction of the cell. The region of the p-type diffusion area 3p, the p-type diffusion area 5p2, the p-type diffusion area 4p, and the power supply line 6 (VDD) corresponding to the width 1 expanded across the cell boundary 31 is shared with the adjacent cell (not illustrated) in the width direction of the cell when the standard cells C2 are arranged in an array.

An n-type diffusion area 5n forming a source node is expanded outward from the cell boundary 31 in the width direction of the cell and it has double the width W1 with the cell boundary 31 put in the middle. The power supply line 6 (VSS), an n-type diffusion area 4n, and an n-type diffusion area 3n are expanded outward from the cell boundary 31 to the same position as the n-type diffusion area 5n at the respective one ends (left side) in the width direction of the cell. The region of the n-type diffusion area 3n, the n-type diffusion area 5n, the n-type diffusion area 4n, and the power supply line 6 (VSS) corresponding to the width W1 expanded across the cell boundary 31 is shared with the adjacent cell (not illustrated) in the width direction of the cell when the standard cells C2 are arranged in an array.

On the other hand, the other end (right side) of the n-type diffusion area 3n terminates at the inner position of the cell at a distance from the cell boundary 31 in the width direction of the cell, and is spaced from the cell boundary 31 with a predetermined distance, similarly to the standard cell C1 shown in FIG. 1A. In the peripheral portion of the cell, a concave portion is provided in the other end of the n-type diffusion area 3n. In other words, the standard cell C2 has a concave portion 32 concaved inside the cell with a predetermined distance from the n-type diffusion area 3n to the cell boundary in the width direction of the cell. When the standard cells C2 are arranged in an array, the transistor area (n-type diffusion area 3n) of the adjacent cell (not illustrated) is disposed in the concave portion 32 in the width direction of the cell.

In this case, the other end of the n-type diffusion area 3n has to secure a space for the diffusion area's design rule from the cell boundary 31. Namely, a space for the diffusion area's design rule has to be secured from the concave portion 32. For example, the end portion of the n-type diffusion area 3n at one side (left side) may be defined as a source diffusion area of the transistor, while the end portion of the n-type diffusion area 3n at the other side (right side) may be defined as a drain diffusion area of the transistor. When the standard cells C2 are arranged in an array, the left end portion (source diffusion area of the transistor) of the n-type diffusion area 3n of the adjacent standard cell C2 is disposed in the concave portion 32.

When the standard cells C2 having the above structure are arranged in an array, the adjacent cells in the width direction of the cell share the source node and the source diffusion area, hence to reduce the actual cell size of each single cell when they are arranged in an array. According to this, compared with the case of arranging the conventional standard cells and the standard cells C1 in an array, this embodiment can drastically reduce the occupation area of the cells in a semiconductor chip, by reducing the size of a semiconductor chip.

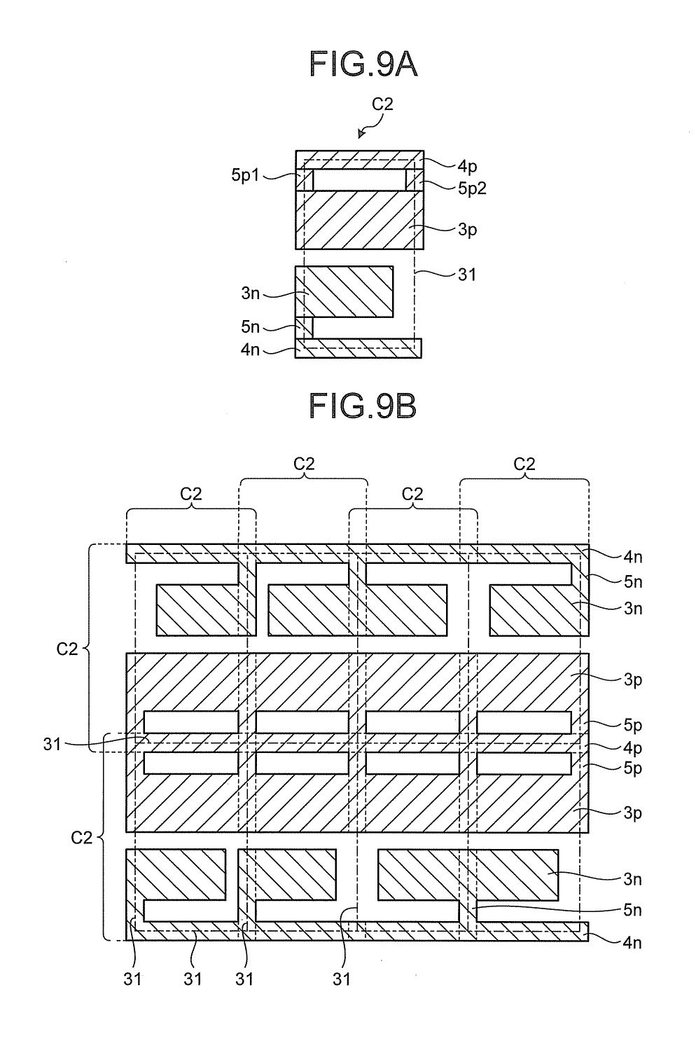

FIGS. 9A and 9B are schematic views for use in describing the structure of the transistor area and the source node area in the standard cell C2 according to the second embodiment. FIG. 9A shows the structure of the transistor area and the source node area in the standard cell C2 as a basic unit. FIG. 9B shows the structure of the transistor areas and the source node areas in the standard cells C2 when the standard cells C2 are arranged in an array. FIGS. 9A and 9B show only the cell boundary 31, the transistor area (the p-type diffusion area 3p and the n-type diffusion area 3n), and the source node (the p-type diffusion area 4p, the p-type diffusion area 5p1, the p-type diffusion area 5p2, the n-type diffusion area 4n, and the n-type diffusion area 5n). FIG. 9B shows an example of sharing the source node and the transistor area on one side or on the both sides with the adjacent cells in the width direction of the cell when the standard cells are arranged in an array. The end portions of the p-type diffusion area 3p on the both sides are shared with the adjacent cells in the width direction of the cell. The end portion of the n-type diffusion area 3n on one side is shared with the adjacent cell in the width direction of the cell. The end portions of the p-type diffusion area 4p on the both sides are shared with the adjacent cells in the width direction of the cell. The p-type diffusion area 5p1 and the p-type diffusion area 5p2 are respectively shared with the adjacent cells.

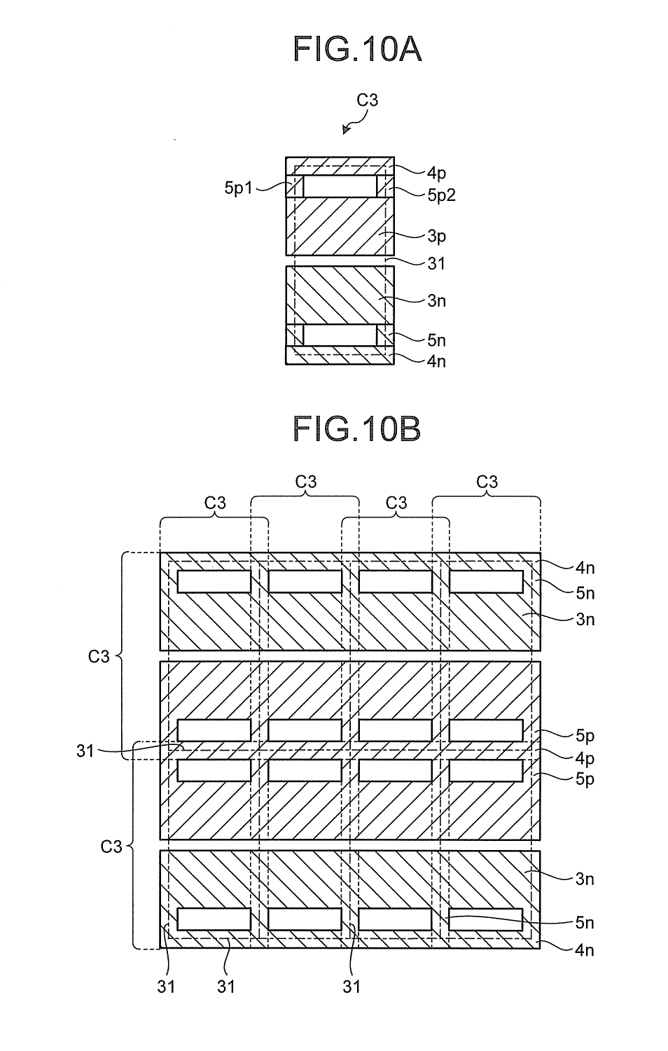

FIGS. 10A and 10B are schematic views for use in describing the structure of the transistor area and the source node area in a standard cell C3 according to the second embodiment. The standard cell C3 is formed in that the transistor area and the source node are expanded across the cell boundary 31 in the width direction of the cell, with the cell boundary 31 sandwiched between the respective end portions of the adjacent cells. FIG. 10A shows the structure of the transistor area and the source node area in the standard cell C3 as a basic unit. FIG. 10B shows the structure of the transistor areas and the source node areas in the standard cells C3 when they are arranged in an array. FIGS. 10A and 10B show only the cell boundary 31, the transistor area (the p-type diffusion area 3p and the n-type diffusion area 3n), and the source node (the p-type diffusion area 4p, the p-type diffusion area 5p1, the p-type diffusion area 5p2, the n-type diffusion area 4n, and the n-type diffusion area 5n). FIG. 10B shows an example of sharing the source node and the transistor area with the adjacent cells on the both sides in the width direction of the cell when the standard cells are arranged in an array. Here, the cell size of the standard cell C2 is reduced through high integration, hence to shorten the width between the cell boundaries 31 in the width direction of the cell.

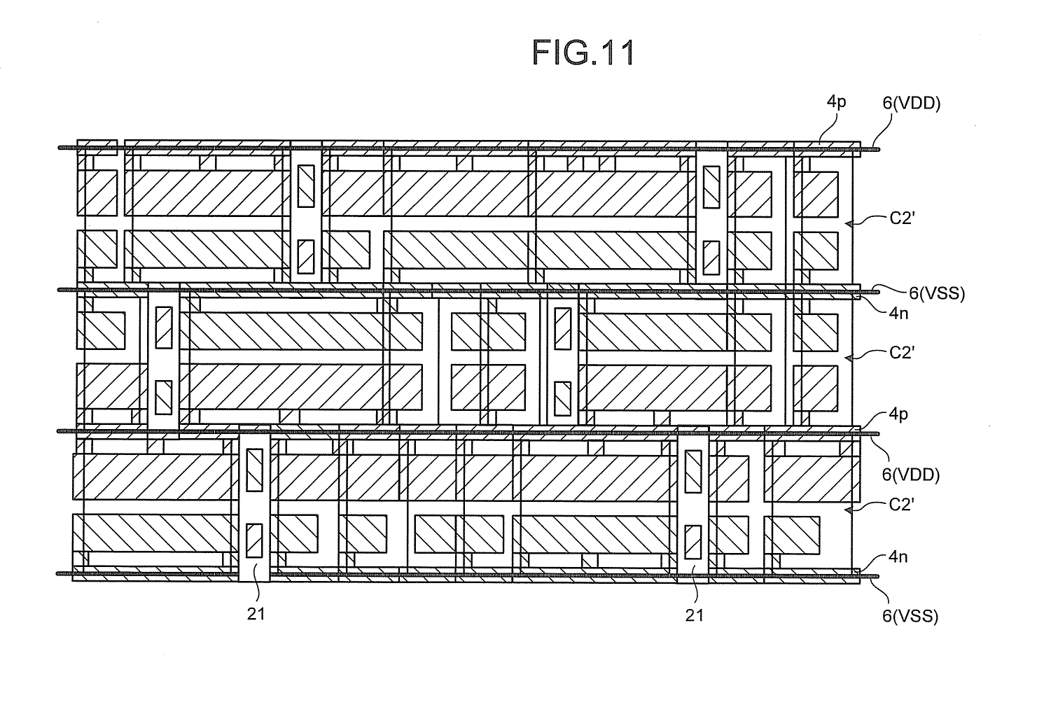

FIG. 11 is a view showing an example of the layout pattern of the standard cells in a semiconductor device according to the second embodiment. In the semiconductor device, a plurality of standard cells C2′ having the same structure as the standard cell C2 according to the second embodiment described above are arranged in an array. As a means for supplying a potential to a well, dedicated cells (tap cell) 21 are arranged in each cell line at some intervals.

In FIGS. 9B and 10B, each standard cell is laid out in a way of sharing each source node at the both sides or at one side of the cell, among the adjacent cells on the both sides of the cell boundary 31, in the width direction of the cell. Thus, each of the standard cell C2 and the standard cell C3 shares the transistor area and the source node with the adjacent cell with the cell boundary 31 put in the middle, in the width direction of the cell, and therefore, the width of the transistor area and the source node in each standard cell can be reduced and the width of a single cell can be reduced compared with the conventional cell. When these cells are laid out, the occupied area by the cells can be remarkably reduced.

As mentioned above, according to the second embodiment, when the identical cells are arranged in an array, the adjacent cells in the width direction of the cells share each source node and each diffusion area of transistor area, thereby reducing the actual single cell size. According to this, when they are arranged in an array, the occupied area by the cells in a semiconductor chip can be remarkably reduced, compared with the case of arranging the conventional standard cells and the standard cells C1 in an array, and the size of a semiconductor chip can be reduced.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A semiconductor device with standard cells arranged in an array, the standard cell comprising:
a first diffusion area with a plurality of transistors formed in a main surface region of a semiconductor substrate is formed in a region sandwiched between two power supply lines arranged above the semiconductor substrate, and
a potential supplying unit is provided, which is formed in the main surface region of the semiconductor substrate by a diffusion layer of the same conductive type as that of the first diffusion area and electrically connected directly to the first diffusion area through a contact from a lower portion of the power supply line, to supply a potential from the power supply line to the first diffusion area.

2. The semiconductor device of claim 1, wherein
the two power supply lines are provided on both end portion in a vertical direction of the standard cell,
the potential supplying unit is formed by
a second diffusion area formed of the same conductive type as that of the first diffusion area in the main surface region of the semiconductor substrate under the power supply line, and
a third diffusion area formed of the same conductive type as that of the first diffusion area in the main surface region of the semiconductor substrate to electrically connect the first diffusion area and the second diffusion area, and
a potential from the lower portion of the power supply line is supplied to the first diffusion area through the contact, the second diffusion area, and the third diffusion area.

3. The semiconductor device of claim 2, wherein
the first diffusion area, the second diffusion area, and the third diffusion area have a protruded portion protruding in the width direction of the standard cell, and
the protruded portion is shared with an adjacent standard cell in the width direction of the standard cell.

4. The semiconductor device of claim 2, wherein
the first diffusion area, the second diffusion area, and the third diffusion area have a protruded portion protruding in the width direction of the standard cell,
the semiconductor substrate has a concave portion concaved inside the standard cell with a predetermined distance from the first diffusion area in the width direction of the standard cell, and
the protruded portion of an adjacent standard cell in the width direction of the standard cell is disposed in the concave portion.

5. The semiconductor device of claim 2, wherein
each of the power supply line and the second diffusion area has a width symmetric with respect to a center line extending along the power supply line, and
an adjacent standard cell in the vertical direction of the standard cell shares the power supply line and the second diffusion area.

6. The semiconductor device of claim 2, wherein
the second diffusion area is wider than the width of the contact in the vertical direction.

7. The semiconductor device of claim 2, wherein
a first power supply line of the two power supply lines is electrically connected to the first diffusion area, the second diffusion area, and the third diffusion area of a first conductive type through the contact, and
a second power supply line of the two power supply lines is electrically connected to the first diffusion area, the second diffusion area, and the third diffusion area of a second conductive type through the contact.

8. The semiconductor device of claim 7, wherein
the first diffusion area of the first conductive type is a p-type diffusion area, and
the first diffusion area of the second conductive type is an n-type diffusion area.

9. The semiconductor device of claim 1, wherein
any wiring for supplying a potential from the power supply line to the first diffusion area is not disposed in an upper layer above the first diffusion area.

10. The semiconductor device of claim 1, wherein
the transistor is an MOS transistor, and
the first diffusion area forms a transistor area of the MOS transistors.

11. A semiconductor device with semiconductor cells arranged in an array, the semiconductor cell comprising:
a first diffusion area with a plurality of transistors formed in a main surface region of a semiconductor substrate is formed in a region sandwiched between two power supply lines arranged above the semiconductor substrate, and
a potential supplying unit is provided, which is formed in the main surface region of the semiconductor substrate by a diffusion layer of the same conductive type as that of the first diffusion area and is electrically connected directly to the first diffusion area through a contact from a lower portion of the power supply line, to supply a potential from the power supply line to the first diffusion area.

12. The semiconductor device of claim 11, wherein
the two power supply lines are provided on both end portion in a vertical direction of the semiconductor cell,
the potential supplying unit is formed by
a second diffusion area formed of the same conductive type as that of the first diffusion area in the main surface region of the semiconductor substrate under the power supply line, and
a third diffusion area formed of the same conductive type as that of the first diffusion area in the main surface region of the semiconductor substrate to electrically connect the first diffusion area and the second diffusion area, and
a potential from the lower portion of the power supply line is supplied to the first diffusion area through the contact, the second diffusion area, and the third diffusion area.

13. The semiconductor device of claim 12, wherein
the first diffusion area, the second diffusion area, and the third diffusion area have a protruded portion protruding in the width direction of the semiconductor cell, and
the protruded portion is shared with an adjacent semiconductor cell in the width direction.

14. The semiconductor device of claim 12, wherein
the first diffusion area, the second diffusion area, and the third diffusion area have a protruded portion protruding in the width direction of the semiconductor cell,
the semiconductor substrate has a concave portion concaved inside the semiconductor cell with a predetermined distance from the first diffusion area in the width direction, and
the protruded portion of an adjacent semiconductor cell in the width direction is disposed in the concave portion.

15. The semiconductor device of claim 12, wherein
each of the power supply line and the second diffusion area has a width symmetric with respect to a center line extending along the power supply line, and
the adjacent semiconductor cell in the vertical direction shares the power supply line and the second diffusion area.

16. A standard cell forming a semiconductor device with a plurality of the standard cells arranged in an array in a semiconductor substrate arranged under a plurality of power supply lines, the standard cell
a first diffusion area with a plurality of transistors formed in a main surface region of the semiconductor substrate is formed in a region sandwiched between the two power supply lines, and
a potential supplying unit is provided, which is formed in the main surface region of the semiconductor substrate by a diffusion layer of the same conductive type as that of the first diffusion area and is electrically connected directly to the first diffusion area through a contact from a lower portion of the power supply line, to supply a potential from the power supply line to the first diffusion area.

17. The standard cell of claim 16, wherein
the potential supplying unit is formed by
a second diffusion area formed of the same conductive type as that of the first diffusion area in the main surface region of the semiconductor substrate in a region corresponding to the lower portion of the power supply line, and
a third diffusion area formed of the same conductive type as that of the first diffusion area in the main surface region of the semiconductor substrate to electrically connect the first diffusion area and the second diffusion area, and
a potential from the lower portion of the power supply line is supplied to the first diffusion area through the contact, the second diffusion area, and the third diffusion area.

18. The standard cell of claim 17, wherein
the first diffusion area, the second diffusion area, and the third diffusion area have a protruded portion protruding in the width direction of the self standard cell.

19. The standard cell of claim 17, wherein
the first diffusion area, the second diffusion area, and the third diffusion area have a protruded portion protruding in the width direction of the self standard cell, and
the semiconductor substrate has a concave portion concaved inside the self standard cell with a predetermined distance from the first diffusion area in the width direction.

20. The standard cell of claim 17, wherein
the second diffusion area has a width symmetric with respect to a center line extending along the power supply line.
